(19) United States
(12) Patent Application Publication
(10) Pub. No.: US 2005/0259498 A1
(43) Pub. Date: Nov. 24, 2005

(54) Asymmetrical programming mechanism for non-volatile memory

(76) Inventor: Peter Nangle, Folsom, CA (US)

Correspondence Address: FISH & RICHARDSON, PC, 12390 EL CAMINO REAL, SAN DIEGO, CA, 92130-2081, US

(21) Appl. No.: 11/191,887

(22) Filed: Jul. 27, 2005

Related U.S. Application Data
(62) Division of application No. 10/044,597, filed on Jan. 9, 2002.

(51) Int. Cl. G11C 5/00

(52) U.S. Cl. 365/226

(57) ABSTRACT

In an embodiment, a phase change non-volatile memory includes a number of memory cells. The memory cells include a phase change material which may transition between two memory state. The transition time to achieve on memory state is longer than the transition time to achieve another memory state. All cells in the memory device may initially be set to the state with the longer transition time. An initial programming operation may have a reduced programming time because all state changes occur at the shorter transition time.

### CROSS-REFERENCE TO RELATED APPLICATIONS

This application is a divisional application of and claims priority to U.S. patent application Ser. No. 10/044,597, filed Jan. 9, 2002.

### BACKGROUND

Certain non-volatile memory devices utilize phase change technology to read and write data. The storage mechanism is typically a reversible change of state of a material or structure. For example, CD-Rewritable (CD-RW) and DVD-RAM optical disk drives use laser-induced structural phase change in an alloy layer on the disk to read and write data. The disk drives use laser energy to heat the material between amorphous and crystalline states to write data, and use the difference in reflectivity between the two states to optically read data.

Another class of phase change non-volatile memory devices utilize the electrical properties of the phase change material to read and write data, taking advantage of the difference in resistivity in the material in the different states. In the amorphous state, a small amount of current will pass, and in the crystalline state, the resistance of the material in that state will limit the current. Such devices may use an electric current to heat the material between amorphous and crystalline states.

The phase change material used in both rewritable optical disk and electrically-addressable memories may exhibit asymmetric switching times between two phases, and hence between memory states. In the manufacturing process, the longer transition time may be assumed for any preprogramming of the phase change memory device which may increase assembly time and reduce production throughput.

### BRIEF DESCRIPTION OF THE DRAWINGS

FIG. 1 is a block diagram of a device for writing to a phase-change memory device according to an embodiment.

FIG. 2 is a plan view of an optical phase-change medium according to an embodiment.

FIG. 3 is a perspective view of a memory device according to an embodiment.

FIG. 4 is a flowchart describing a fast preprogramming operation according to an embodiment.

### DETAILED DESCRIPTION

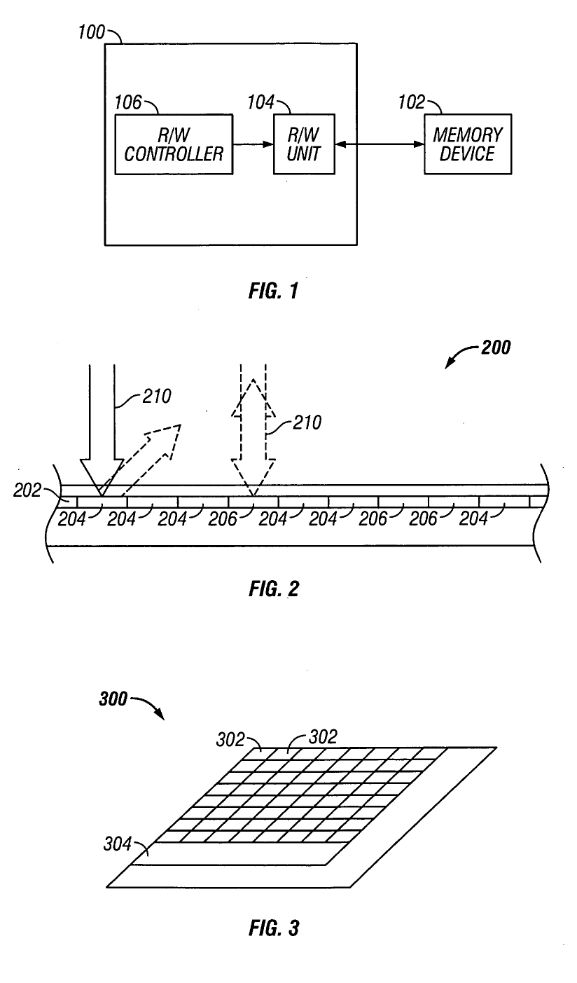

FIG. 1 illustrates a device 100 for programming a non-volatile phase-change memory device 102 according to an embodiment. The mechanism for storing data in the phase-change memory device 102 involves a change in state of a material or structure. For example, the storage mechanism may involve a change between an amorphous state of an material to a crystalline state of the material. The phase change may be temporally asymmetric, that is, the state change in one direction (e.g., amorphous-to-crystalline) may take longer than the state change in the other direction (e.g., crystalline-to-amorphous). This asymmetry in transition between states translates directly to an asymmetry in transition between memory states (e.g., LOW/HIGH, or 0/1 memory transitions for binary memory devices). The device 100 utilizes this asymmetry to decrease preprogramming of the phase-change memory device and provide dual mode (“fast” and “normal”) programming in subsequent programming operations.

One class of non-volatile memory devices utilize the optical properties of phase change materials to store and access data. For example, rewritable optical disk technologies such as CD-RW and DVD-RAM utilize the difference in the reflectivity of a phase change material in an amorphous state and a crystalline state to read and write data. Such an optical disk 200 includes a layer of a phase change material 202, typically including silver, indium, antimony, and/or tellurium, embedded in the plastic base of the disk, as shown in FIG. 2. In its original state, this layer has a rigid polycrystalline structure. A laser beam in the disk drive selectively heats areas in the layer to 900°-1,300° F. degrees. Where the beam strikes, the heat melts the crystals to a non-crystalline, or amorphous, phase. These areas reflect less light than the unchanged, crystalline areas surrounding them.

The disks are read optically with a weaker laser beam 210. When the weaker laser beam strikes a non-crystalline area 204, the beam is scattered and not picked up by the light-sensitive diode in the read head. These amorphous areas are referred to as “pits” (corresponding to the analogous topographical feature on standard CDs) and represent bits having a “1” value. When the laser beam strikes a crystalline area 206, the beam is reflected and is reflected directly to the diode. These crystalline areas are referred to as “lands” and represent bits having a “0” value.

To erase data or to change an amorphous (pit) area back to a crystalline (land) area, the disk drive causes the laser beam to heat the amorphous area to a temperature between the glass transition temperature and the melting temperature, typically about 400° F. degrees. This causes nucleation and crystal growth, recrystallizing the material in a short time.

Another class of non-volatile memory devices utilize the electrical properties of phase change materials. For example, the memory device 300 shown in FIG. 3 may utilize a chalcogenide alloy, similar to that used in many CD-RW and DVD-RAM optical disks, as a phase change material. The memory device 300 may be a non-volatile memory, which includes an array of individually addressable memory cells 302 arranged in rows and columns. Each memory cell includes a phase change material that has different electrical properties in different states, e.g., amorphous and crystalline states. The electrical properties may include resistivity. Individual cells may represent different bits of stored information. Such an electrically addressable non-volatile phase change memory device may be used as direct replacements for other types of non-volatile memories such as Flash memories and non-volatile memories such as DRAMs.

In normal operation, a circuit 304 may be used to write, erase, and read information stored in the memory cells 302. The circuit 304 may be used to address individual memory cells 302 and to provide electrical energies used to change the state of the material and to read the data in the cell.

The circuit 104 may provide electrical energy to convert a small volume of the phase change material in one or more selected memory cells to a crystalline or to an amorphous state, which may be read as a “0” or “1” value, respectively. The phase conversion may be accomplished by heating the material. However, unlike in the rewritable optical disks described above (CD-RW and DVD-RAM), the circuit 304 provides the energy used to heat the material instead of a laser beam.

Heating the material in the crystalline phase above its melting point causes the material to lose its crystalline structure. When the material then cools below the glass transition temperature, the material is locked in its amorphous phase. The amorphous phase may be stable at room temperature, but the rate of nucleation and growth of crystallites may increase rapidly as the temperature of the material is raised toward the melting temperature. To switch the memory element back to the crystalline phase, the circuit 104 heats the material between the glass transition temperature and the melting temperature, causing rapid nucleation and crystal growth.

A memory cell may be read by applying an electric field to the cell. The material has a lower resistance in the crystalline state, and a small current will pass. The material has a relatively higher resistance in the amorphous state, and the applied voltage and the resistance of the material will limit the current through the cell.

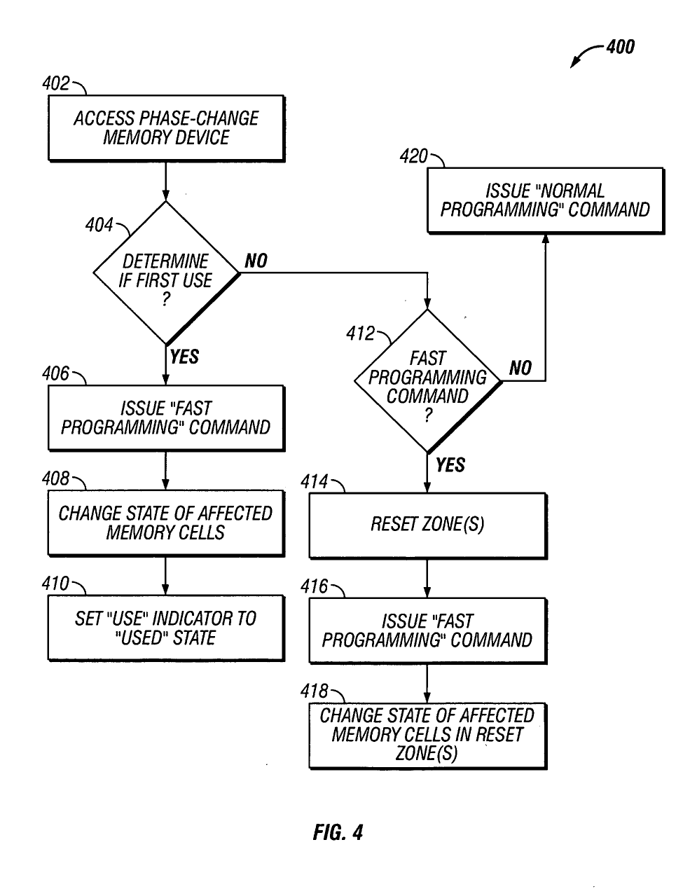

It may be desirable to preprogram the memory device during the manufacturing process, for example, after the memory device is mounted on a circuit board but before it is installed in a larger device. FIG. 4 illustrates a fast preprogramming operation 400 that takes advantage of the temporal asymmetry between the state transitions in the phase change memory device 102.

Prior to an initial programming of the memory device 102, the phase change material in the memory cells may be preset to the state that takes the longer to achieve. For example, in a chalcogenide alloy such as that used in the CD-RW and DVD-RAM disc 200 and the electrically-addressable non-volatile phase-change memory device 300, the preset state may be the crystalline phase. The memory device 102 may be accessed by a reader/writer (R/W) unit 104 in the programming device 100 (block 402). A R/W controller 106 determines if the memory devices 102 is being preprogrammed (block 404).

The device manufacturer may provide the unused memory devices in a preset state so that the system or equipment manufacturer may assume a memory device is in a preset state before installing it. Alternatively, the memory device may include a use indicator, such as a “first time used” bit, which may be read by the R/W unit 104 during initialization and communicated to the R/W controller 106. If the R/W controller 106 determines that the memory device 102 is in the preset state for preprogramming, the R/W controller may issue a “fast programming” command to the R/W unit 104 (block 406). In the fast programming mode, only the cells that need to change (e.g., from the crystalline (HIGH) state to the amorphous (LOW) state) are affected and only the shorter transition time is required (block 408). The R/W unit 104 may then set the user indicator to the “used” state to indicate that the memory device 102 is not in the preset state (block 410).

The programming device may utilize the fast programming mode after the memory device 102 has been preprogrammed. Memory cells in the memory device may be partitioned into different areas, or zones, which may be reset into the preset state during normal use of the memory device. The memory cells in a reset zone could be programmed faster than memory cells in other zones, since only cells that needed to be switched in the faster transition direction would be affected.

Fast mode programming of reset zones in the memory device 102 may be useful, for example, in Internet devices to enable faster on-line downloads. The user of a device including the programming device 100 and phase-change memory device 102 may issue a command to initiate the fast programming mode (block 412), for example, in anticipation of a data download operation. The R/W controller 106 controls the R/W unit 104 to access and reset memory cells in a selected zone or zones (block 414). The R/W controller 106 then issues the fast programming command (block 416) and the R/W unit 104 writes the downloaded data to the memory device, only changing the state of cells in the reset zone(s) that are to be transitioned to the amorphous phase (block 418).

If the memory device 102 has already been preprogrammed and no fast programming command has been issued, the R/W controller 106 may issue a “normal programming” command to control the R/W to program the memory device in a normal programming mode. Alternatively, the normal programming mode may be the default programming mode for each programming operation performed by the R/W unit 104, which only changes if the fast programming command is issued. In the normal programming mode, memory cells may be in either memory state and are transitioned between the two states as needed.

A number of embodiments have been described. Nevertheless, it will be understood that various modifications may be made without departing from the spirit and scope of the invention. For example, blocks in the flowchart may be skipped or performed out of order and still produce desirable results. Accordingly, other embodiments are within the scope of the following claims.

1. A method comprising:
causing a device including a plurality of memory cells asymmetric transition times between at least two states to be programmed by
in a fast write mode, exclusively transitioning a plurality of said memory cells from a first state having a longer transition time to achieve to a second state having a shorter transition time to achieve, and
in a normal write mode, overwriting a plurality of memory cells, said overwriting comprising transitioning a plurality of said memory cells in the first state to the second state and transitioning another plurality of said memory cells in the second state to the first state,
wherein said transitioning comprises heating each of said memory cells by activating an electrically addressable transistor in a memory cell.

2. The method of claim 1, wherein each memory cell includes a phase change material.

3. The method of claim 2, wherein the phase change material comprises a chalcogenide alloy.

4. The method of claim 1, further comprising:
determining if the device has been written to; and
setting an indicator to a used status in response to determining that the device has been written to.

5. A method comprising:
setting a plurality of memory cells in one of a plurality of zones of a memory device with asymmetric transition times between at least two states to a first state having a transition time to achieve; and
in a fast write mode, exclusively programming memory cells in the one or more zones by exclusively transitioning cells from the first state to a second state having a shorter transition time to achieve; and
in a normal write mode, overwriting a plurality of memory cells outside of said one or more zones, said overwriting comprising transitioning a plurality of said memory cells in the first state to the second state and transitioning another plurality of said memory cells in the second state to the first state,
wherein said transitioning comprises heating each of said memory cells by activating an electrically addressable transistor in a memory cell.

6. The method of claim 5, further comprising:
receiving a command to set memory cells in the zone to the first state; and
setting said memory cells to the first state.

7. The method of claim 5, further comprising setting the memory cells to the first state after a first use of the device.

8. The method of claim 6, further comprising:
receiving an indication that the memory device is preparing to initiate a data download; and
setting said plurality of memory cells in the zone to the first state.

9. An apparatus comprising:
a writer unit operative to write data to a memory device having an asymmetric transition time between two memory states, wherein a transition from a first memory state to a second memory state takes longer than a transition from the second memory state to the first memory state, the writer unit comprising a controller operative to selectively control electrically transistors in said plurality of memory cells to heat each of said plurality of memory cells; and
a controller operative to
in a fast write mode, control the write unit to write exclusively to memory cells to be transitioned to the first memory state, and
in a normal write mode, overwrite a plurality of memory cells, said overwriting comprising transitioning a plurality of said memory cells in the first state to the second state and transitioning another plurality of said memory cells in the second state to the first state.

10. The apparatus of claim 9, wherein the apparatus comprises a non-volatile phase change memory device.

11. The apparatus of claim 9, further comprising a reader unit operative to determine if a use of the memory device is a first use, wherein the controller is operative to control the write unit to write exclusively to memory cells to be transitioned to the first memory state in response to determining that the use is the first use.

12. The apparatus of claim 9, wherein the controller is operative to control the write unit to reset a plurality of memory cells in a zone to the second memory state.

13. The apparatus of claim 12, wherein the controller is operative to control the write unit to write exclusively to memory cells in the zone.

14. An article comprising a machine-readable medium including machine-executable instructions, the instructions operative to cause a machine to:
set a plurality of memory cells in one of a plurality of zones of a memory device with asymmetric transition times between at least two states to a first state having a transition time to achieve; and
in a fast write mode, exclusively program memory cells in the one or more zones by exclusively transitioning cells from the first state to a second state having a shorter transition time to achieve; and
in a normal write mode, overwrite a plurality of memory cells outside of said one or more zones, said overwriting comprising transitioning a plurality of said memory cells in the first state to the second state and transitioning another plurality of said memory cells in the second state to the first state,
wherein said transitioning comprises heating each of said memory cells by activating an electrically addressable transistor in a memory cell.

15. The article of claim 14, further comprising instructions operative to cause the machine to:
receive a command to set memory cells in the zone to the first state; and
set said memory cells to the first state.

16. A method comprising:
causing a device including a plurality of memory cells, each including a phase change material, to be programmed with asymmetric transition times between at least two states by exclusively transitioning a plurality of said cells from a first state having a longer transition time to achieve to a second state having a shorter transition time to achieve,
wherein said transitioning comprises heating each of said memory cells by activating a circuit to selectively provide electrical energy to at least one of said memory cells.
